(19) United States
(12) Patent Application Publication
(10) Pub. No.: US 2025/0210482 A1
(43) Pub. Date: Jun. 26, 2025

(54) STACKED PACKAGE DEVICE WITH INTERCONNECTED CONDUCTIVE BUMPS

(71) Applicant: POWERTECH TECHNOLOGY INC., Hsinchu County (TW)

(72) Inventors: HUNG HSIN HSU, Hsinchu County (TW); LIEN CHIA CHANG, Hsinchu County (TW)

(73) Assignee: POWERTECH TECHNOLOGY INC., Hsinchu County (TW)

(21) Appl. No.: 18/937,603

(22) Filed: Nov. 5, 2024

(30) Foreign Application Priority Data
Dec. 20, 2023 (TW) 112149749

(51) Int. Cl. H01L 23/498; H01L 23/00; H01L 23/538; H01L 25/065

(52) U.S. Cl. CPC H01L 23/49816; H01L 23/5385; H01L 23/5389; H01L 24/32; H01L 25/0657; H01L 24/16; H01L 24/73; H01L 2224/16227; H01L 2224/26175; H01L 2224/32225; H01L 2224/73204; H01L 2225/0652; H01L 2225/06558

(57) ABSTRACT

A stacked package device has a first package and a second package vertically stacked and electrically connected to each other. One or each of the first package and the second package includes a first substrate, a second substrate and multiple conductive bumps. A first flip-chip and a second flip-chip are respectively mounted on opposite surfaces of the first substrate and the second substrate. The multiple conductive bumps are electrically connected between the opposite surfaces of the first substrate and the second substrate to achieve signal transmission between the first flip-chip and the second flip-chip. The use of the multiple conductive bumps avoids the structure damage resulting from thermal stress. Since no encapsulant is provided to cover each flip-chip, the problem of separation between the encapsulant and the substrate is avoided.

### CROSS REFERENCE TO RELATED APPLICATIONS

This non-provisional application claims the benefit under 35 U.S.C. § 119 (a) to Patent Application No. 112149749 filed in Taiwan on Dec. 20, 2023, which is hereby expressly incorporated by reference into the present application.

### BACKGROUND OF THE INVENTION

### 1. Field of the Invention

The present invention relates to a stacked package device, particularly to a stacked package device comprising conductive bumps electrically interconnected between different substrates.

### 2. Description of the Related Art

In order to integrate different types of or multiple package elements, package on package (PoP) technology is proposed to stack multiple packages into a miniaturized component to reduce space occupation as much as possible in electronic products.

With reference to FIG. 4, according to conventional PoP technology, a top package 100 is placed above and electrically connected to a bottom package 200. Both the top package 100 and the bottom package 200 contain a respective chip. For a high bandwidth PoP, the bottom package 200 may have a top substrate 201, a bottom substrate 202 and a plurality of conductive pillars 232 vertically interconnected between the top substrate 201 and the bottom substrate 202. An encapsulant 240 (EMC) is provided to fill space between the top substrate 201 and the bottom substrate 202 and encapsulate the chip inside the bottom package 200.

The conductive pillars 230 provided between the top substrate 201 and the bottom substrate 202 are usually formed by the electroplating process. However, the conductive pillars 230 may have voids formed therein during the electroplating process. When the conductive pillars 230 are subjected to thermal stress, the voids may cause damage to the conductive pillars 230 and deteriorate their electrical transmission capability. Further, because the encapsulant 240 and the two substrates 201, 202 have different coefficients of thermal expansion (CTE), the separation between the encapsulant 240 and the two substrates 201, 202 may occur when they are heated.

### SUMMARY OF THE INVENTION

An objective of the present disclosure is to provide a stacked package device free from encapsulant so as to mitigate possible damages caused by thermal stress to the structure of the stacked package.

The stacked package device comprises a first substrate, a second substrate, multiple conductive bumps and multiple external connecting members.

The first substrate has an outer surface and an inner surface opposite to each other, the outer surface is electrically connected to the first package, and the inner surface has a first flip-chip electrically mounted thereon.

The second substrate has an outer surface and an inner surface opposite to each other, the inner surface of the second substrate facing the inner surface of the first substrate, and a second flip-chip being electrically mounted on the inner surface of the second substrate.

The multiple conductive bumps are distributed around the first flip-chip and the second flip-chip and electrically connected between the inner surface of the first substrate and the inner surface of the second substrate.

The multiple external connecting members are provided on the outer surface of the second substrate.

Based on the above, the stacked package device of the invention, via the multiple conductive bumps to electrically connect the first substrate and the second substrate, rather than forming copper pillar by electroplating, the problem of structural damage to the copper pillar due to thermal stress can be avoided. Furthermore, no encapsulant (EMC) is provided between the first substrate and the second substrate to cover chips, which prevents the encapsulant from separating from the substrates.

Other objectives, advantages and novel features of the invention will become more apparent from the following detailed description when taken in conjunction with the accompanying drawings.

### BRIEF DESCRIPTION OF THE DRAWINGS

FIG. 1 is a cross section view of a stacked package device according to an embodiment of the invention;

FIG. 2 is a cross section view of a stacked package device according to another embodiment of the invention;

FIG. 3 is a cross section view of a stacked package device according to yet another embodiment of the invention; and

FIG. 4 is a cross section view of a conventional stacked package device.

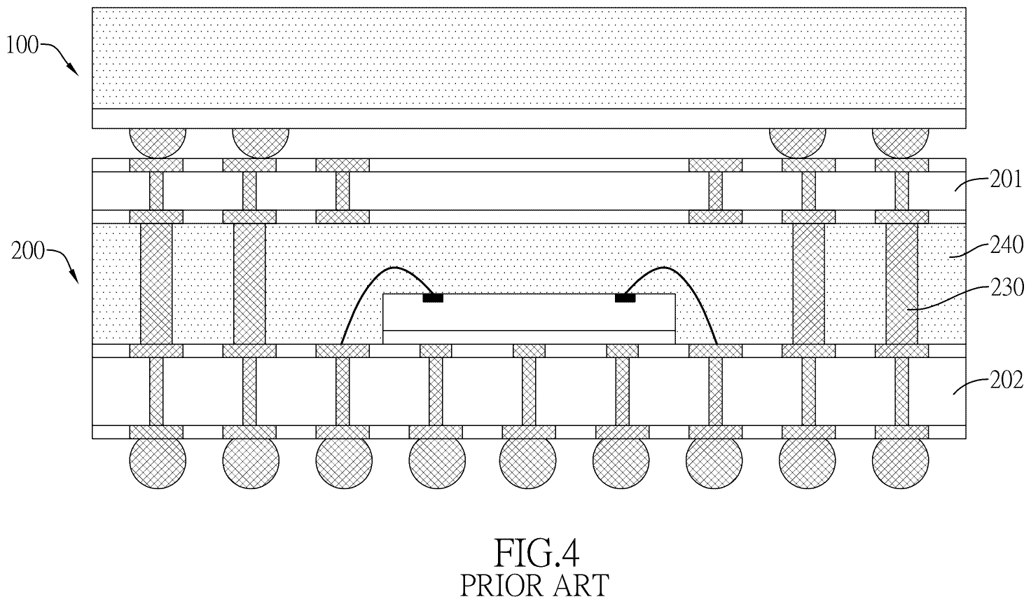

### DETAILED DESCRIPTION OF THE INVENTION

Directional terms as used herein, for example, up, down, right, left, front, back, top, bottom are made only with reference to the figures as illustrated and are not intended to imply absolute orientation unless otherwise specified.

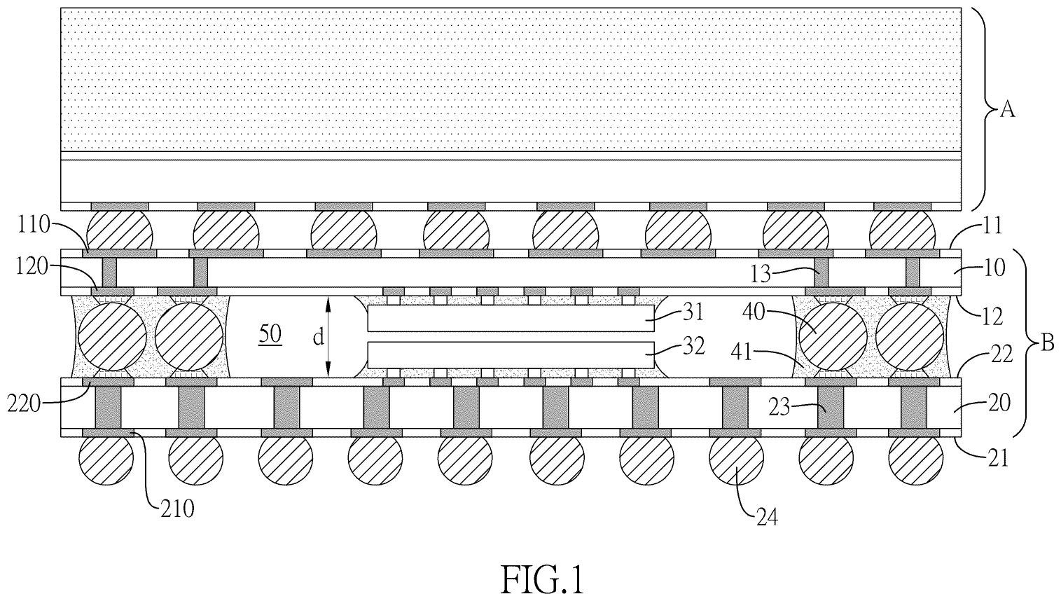

With reference to FIG. 1, according to one embodiment of the invention, a stacked package device comprises a first package A and a second package B. The first package A is vertically mounted above the second package B. Any one or both of the first package A and the second package B may have configuration as described below. In the embodiment, the first package A May be a package of any type and does not have to include specific components therein. As an example, the first package A may contain a memory chip therein. The second package B comprise a first substrate 10, a second substrate 20 and multiple conductive bumps 40 as shown in the drawings.

3 The first substrate 10 includes an outer surface 11 and an inner surface 12 opposite to each other. The outer surface 11 that faces the first package A has multiple outer pads 110 provided thereon for electrically connecting to the first package A. For example, the outer pads 110 are electrically connected to the first package A through respective solder balls.

The inner surface 12 of the first substrate 10 is a flat surface and a first flip-chip 31 is attached on the inner surface 12. A plurality of contacts formed on a bottom of the first flip-chip 31 is electrically connected to the inner surface 12. Underfill material may fill space between the bottom of the first flip-chip 31 and the first substrate 10. Multiple inner pads 120 are formed on the inner surface 12 around the first flip-chip 31 and electrically connected to the respective outer pads 110 through a first redistribution layer 13 in the first substrate 10.

The second substrate 20 includes an outer surface 21 and an inner surface 22 opposite to each other. The inner surface 22 faces the inner surface 12 of the first substrate 10. A second flip-chip 32 is mounted on the inner surface 22 of the second substrate 20, where a plurality of contacts formed on a bottom of the second flip-chip 32 is electrically connected to the inner surface 22. Multiple inner pads 220 are formed on the inner surface 22 around the second flip-chip 32. Non-active surfaces of both the first flip-chip 31 and the second flip-chip 32 face to each other, but are separated by a gap. Underfill may be provided to fill space between the second flip-chip 32 and the second substrate 20. When filling the underfill under the first flip-chip 31 or the second flip-chip 32, voids may occur in the underfill during the curing process. If there is moisture inside the underfill, these voids allow the moisture to escape from inside, preventing the moisture from trapping in the space between the chip and the substrate.

Multiple outer pads 210 formed on the outer surface 21 are electrically connected to the respective inner pads 220 through a second redistribution layer 23 in the second substrate 20. Multiple external connecting members 24 such as solder balls are provided on the outer pads 210 as connecting pads of the stacked package device for electrically connecting outside.

The multiple conductive bumps 40 are electrically connected between the first substrate 10 and the second substrate 20 and contact the respective inner pads 120, 220. According to one embodiment, each conductive bump 40 is a solid metal bump, such as copper bumps, solder balls, etc. According to another embodiment, each conductive bump 40 is made of a metal core coated with a conductive layer of a different material, for example a copper core coated with a tin layer. According to yet another embodiment, each conductive bump 40 is made of an insulative core coated with a conductive layer. Underfill 41 is applied to fill space between the first substrate 10 and the second substrate 20 and among these conductive bumps 40 to comprehensively cover and protect each conductive bump 40. The underfill 41 prevents the conductive bumps 40 from separating from the first substrate 10 and the second substrate 20 due to stress. A chip accommodating chamber 50 is formed between the first substrate 10 and the second substrate 20 and surrounded by the underfill 41. Both the first flip-chip 31 and the second flip-chip 32 are located in the chip accommodating chamber 50 with their non-active surfaces and lateral surfaces exposed in the chip accommodating chamber 50.

In addition to electrical connection, the conductive bumps 40 also function as supporting elements to maintain an appropriate distance “d” between the first substrate 10 and the second substrate 20. In an embodiment, the diameter of each conductive bump 40 is greater than the sum of the heights of the first flip-chip 31 and the second flip-chip 32.

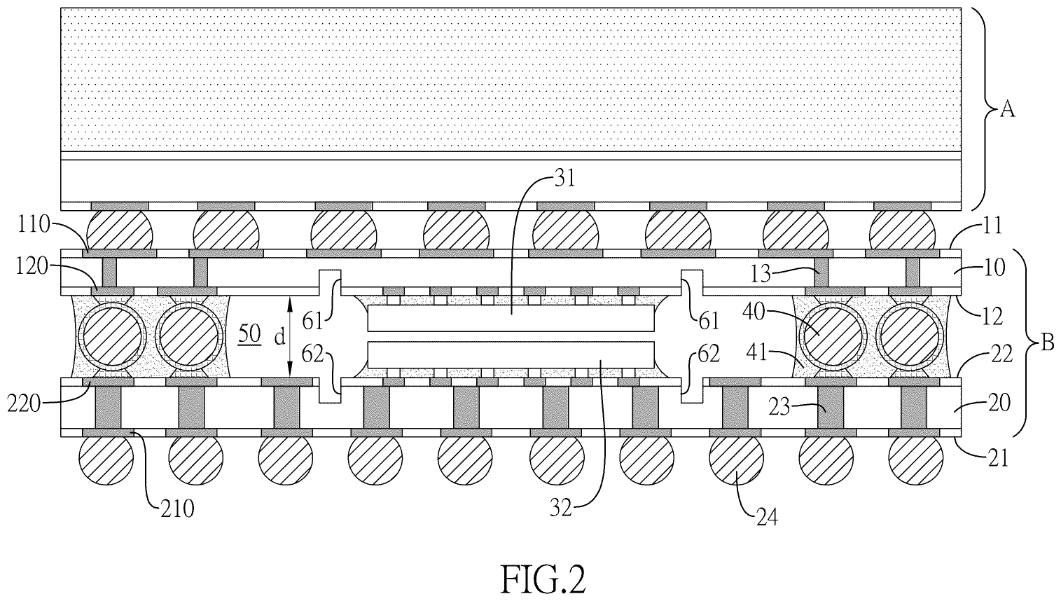

With reference to FIG. 2, according to another embodiment, a first annular groove 61 is formed in the inner surface 12 of the first substrate 10 and around the first flip-chip 31, and a second annular groove 62 is formed in the inner surface 22 of the second substrate 20 and around the second flip-chip 32. Both the first annular groove 61 and the second annular grove 62 are within the chip accommodating chamber 50. For anti-overflow effect, the first annular groove 61 and the second annular grove 62 prevent excessive underfill 41 from flowing around when injecting the underfill 41.

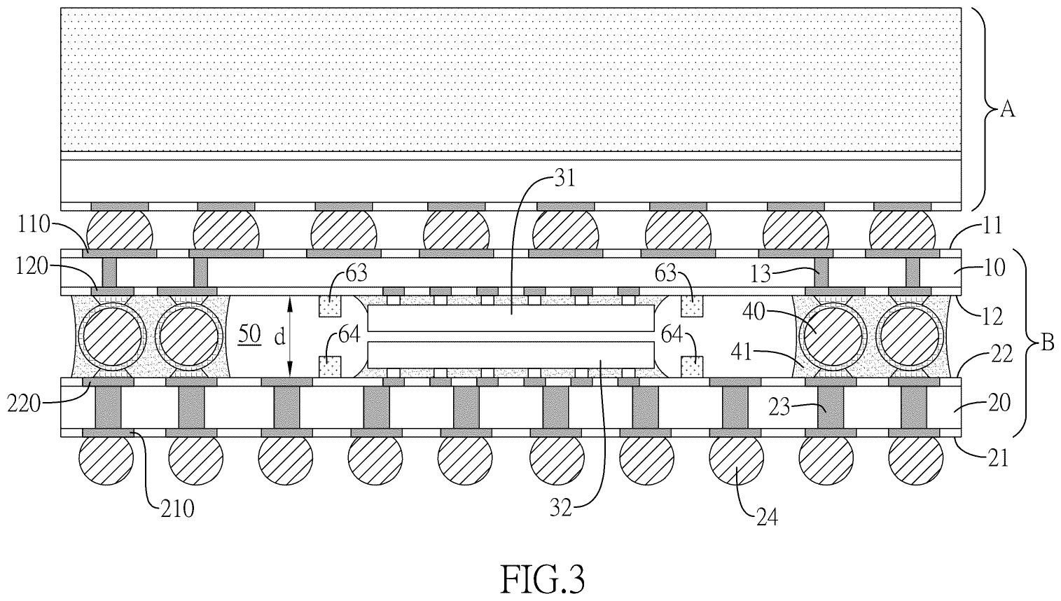

With reference to FIG. 3, according to yet another embodiment, a first annular dam 63 is formed on the inner surface 12 of the first substrate 10 and around the first flip-chip 31, and a second annular dam 64 is formed on the inner surface 22 of the second substrate 20 and around the second flip-chip 32. Both the first annular dam 63 and the second annular dam 64 are within the chip accommodating chamber 50. When injecting the underfill 41, the first annular dam 63 and the second annular dam 64 block excessive underfill 41 from spreading around.

The invention uses solid conductive bumps 40 to electrically connect the first substrate 10 and the second substrate 20 in the second package B, and injects the underfill 41 to cover conductive bumps 40. Since there are no conductive members formed by electroplating processes, damage caused by thermal stress is prevented. Furthermore, no encapsulant (EMC) is applied to cover both the first substrate 10 and the second substrate 20, so that the problem of separation between the encapsulant and the substrates resulting from their inconsistent coefficients of thermal expansion can be avoided.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A stacked package comprising:
a first package;
a second package connected to the first package in a stacked management, the second package comprising:
a first substrate having an outer surface and an inner surface opposite to each other, the outer surface electrically connected to the first package, and a first flip-chip electrically mounted on the inner surface;
a second substrate having an outer surface and an inner surface opposite to each other, the inner surface of the second substrate facing the inner surface of the first substrate, and a second flip-chip electrically mounted on the inner surface of the second substrate;
multiple conductive bumps distributed around the first flip-chip and the second flip-chip and electrically connected between the inner surface of the first substrate and the inner surface of the second substrate; and
multiple external connecting members provided on the outer surface of the second substrate.

2. The stacked package as claimed in claim 1 comprising:
a first annular groove formed in the inner surface of the first substrate and around the first flip-chip; and
a second annular groove formed in the inner surface of the second substrate and around the second flip-chip.

3. The stacked package as claimed in claim 1 comprising:
a first annular dam formed on the inner surface of the first substrate and around the first flip-chip; and
a second annular dam formed on the inner surface of the second substrate and around the second flip-chip.

4. The stacked package as claimed in claim 1, wherein non-active surfaces of the first flip-chip and the second flip-chip face to each other but are separated by a gap.

5. The stacked package as claimed in claim 1, wherein each conductive bump is made of a metal core coated with a conductive layer.

6. The stacked package as claimed in claim 1, wherein each conductive bump is made of an insulative core coated with a conductive layer.

7. The stacked package as claimed in claim 1, wherein underfill is provided to fill space among the conductive bumps and between the first substrate and the second substrate to comprehensively cover each conductive bump;
a chip accommodating chamber is defined between the first substrate and the second substrate and surrounded by the underfill; and
the first flip-chip and the second flip-chip are placed in the chip accommodating chamber.

8. The stacked package as claimed in claim 1, wherein non-active surfaces and lateral surfaces of both the first flip-chip and the second flip-chip are exposed.

9. The stacked package as claimed in claim 1, wherein
multiple inner pads and outer pads are respectively formed on the inner surface and the outer surface of the first substrate, and the inner pads are electrically connected to the respective outer pads through a first redistribution layer in the first substrate; and
multiple inner pads and outer pads are respectively formed on the inner surface and the outer surface of the second substrate, and the inner pads of the second substrate are electrically connected to the respective outer pads of the second substrate through a second redistribution layer in the second substrate; and
the multiple conductive bumps are electrically connected between the inner pads of the first substrate and the inner pads of the second substrate.

10. The stacked package device as claimed in claim 1, wherein each of the multiple conductive bumps has a diameter greater than a sum of heights of the first flip-chip and the second flip-chip.
